(19) United States
(12) Patent Application Publication
(10) Pub. No.: US 2024/0343557 A1
(43) Pub. Date: Oct. 17, 2024

(54) MICROMECHANICAL DIAPHRAGM SYSTEM

(71) Applicant: Robert Bosch GmbH, Stuttgart (DE)

(72) Inventors: Jochen Reinmuth, Reutlingen (DE); Christoph Schelling, Stuttgart (DE); Thomas Buck, Tamm (DE)

(21) Appl. No.: 18/614,036

(22) Filed: Mar. 22, 2024

(30) Foreign Application Priority Data
Apr. 17, 2023 (DE) 10 2023 203 463.8

(51) Int. Cl. B81B 3/00; B81C 1/00

(52) U.S. Cl. CPC B81B 3/007; B81C 1/00158; B81B 2201/0257; B81B 2201/0264; B81B 2203/0127; B81B 2203/0163; B81B 2203/0315; B81B 2203/0361; B81B 2203/04; B81C 2201/0105; B81C 2201/056

(57) ABSTRACT

A micromechanical diaphragm system including a first diaphragm and a second diaphragm and spacer elements which are arranged between the first diaphragm and the second diaphragm. At least one spacer element has a first supporting element and a second supporting element. The first supporting element faces the first diaphragm. The second supporting element faces the second diaphragm. The first supporting element and the second supporting element are connected via a spring element.

### CROSS REFERENCE

The present application claims the benefit under 35 U.S.C. § 119 of German Patent Application No. DE 10 2023 203 463.8 filed on Apr. 17, 2023, which is expressly incorporated herein by reference in its entirety.

### FIELD

The present invention relates to a micromechanical diaphragm system. Furthermore, the present invention relates to a micromechanical component having such a diaphragm system and to a production method for such a diaphragm system.

### BACKGROUND INFORMATION

Microphones which contain a capacitively readable microelectromechanical system (MEMS) are particularly powerful with regard to performance features such as signal-to-noise ratio, energy consumption, and further processability. This has resulted in electret microphones being largely replaced by MEMS microphones. Such MEMS microphones can have a double diaphragm through which a significant increase in the signal-to-noise ratio is possible. In this concept, fluidic damping between a rigid back electrode (backplate) and the movable back-pressure diaphragm is almost completely eliminated. This is achieved in that, instead of the back electrode, a center electrode is mounted in a negative-pressure region between two diaphragms coupled to one another. The diaphragms are generally connected to one another by support columns in order to be robust to an external pressure. In addition to the use as microphones, such microelectromechanical systems having a double diaphragm can also be used as a loudspeaker or as a pressure sensor.

MEMS microphones are described in German Patent Application No. DE 10 2014 212 340 A1 and U.S. Pat. No. 10,362,408 B1. One problem of these microelectromechanical systems having a double diaphragm is the high flexural strength of the double-diaphragm systems. Therefore, either large double diaphragms must be used to produce a sensitive microphone, or the microphones can only be produced with relatively low sensitivity. The high flexural strength is essentially caused by support columns that are necessary between the two diaphragms in order to avoid a collapse of the diaphragms due to the external pressure. In order to generate a soft double diaphragm, the thickness of the individual diaphragms can be reduced on the one hand. However, in order to keep the now softer individual diaphragms from collapsing, more support elements have to be used, which in turn leads to an undesired stiffening of the overall diaphragm system. In principle, the support columns can also be designed to be small in order to enable a certain mobility. However, since the support columns have to absorb the entire pressure which loads the individual diaphragms, a reduction is only possible to a certain extent. Furthermore, it is possible to increase the distance between the diaphragms in order to obtain a softer overall system by using higher support columns. However, analyses show that the flexural strength of the overall system can even increase as a result of the higher distance due to the coupling of the support elements. The support columns can be referred to as support elements.

### SUMMARY

It is an object of the present invention to provide a micromechanical diaphragm system which does not have the aforementioned problems with regard to the flexural strength or at least only has them to a lesser extent. A further object of the present invention is to provide an improved micromechanical component having such a micromechanical diaphragm system. A further object of the present invention is to provide a production method for such a micromechanical diaphragm system. This object may be achieved by features of the present invention. Advantageous embodiments and developments of the present invention are disclosed herein.

The present invention relates to a micromechanical diaphragm system. According to an example embodiment of the present invention, the micromechanical diaphragm system includes a first diaphragm and a second diaphragm and spacer elements which are arranged between the first diaphragm and the second diaphragm. At least one spacer element has a first supporting element and a second supporting element. The first supporting element faces the first diaphragm. The second supporting element faces the second diaphragm. The first supporting element and the second supporting element are connected via a spring element.

Lateral mobility of the first supporting element relative to the second supporting element can be achieved by the spring element. Flexural strength of the micromechanical diaphragm system can thereby be reduced since the bending-induced different movements of the diaphragms relative to one another can be compensated for by the spring element. Such a micromechanical diaphragm system thus has less flexural strength than the diaphragm systems from the related art. As a result, more sensitive microphones having the same area or smaller microphones having the same sensitivity are possible, for example.

The example embodiments described below describe the present invention by way of example on the basis of diaphragms. However, they are analogously transferable to bending beams and bending beam/diaphragm systems.

According to an example embodiment of the present invention, the diaphragms can be arranged substantially in parallel. This can mean that an angle between the main extension planes of the diaphragms is less than 5 degrees, in particular less than 2 degrees, and preferably 0.

A plurality of spacer elements can be designed in such a way that they each have a first supporting element and a second supporting element, wherein the first supporting element in each case faces the first diaphragm and the second supporting element in each case faces the second diaphragm, and the first supporting element and the second supporting element are in each case connected via a spring element.

In one example embodiment of the micromechanical diaphragm system of the present invention, at least one spacer element has a further first supporting element. The further first supporting element and the second supporting element are connected via a further spring element. This configuration makes it possible to design the spacer element to be more stable, thus making a collapse of the micromechanical diaphragm system more unlikely or preventing it.

In one example embodiment of the micromechanical diaphragm system of the present invention, the spring element and the further spring element form a double spiral, in particular an Archimedean double spiral, consisting of a spiral, in particular an Archimedean spiral, and a further spiral, in particular a further Archimedean spiral. The second supporting element is arranged in the spiral center between the spiral arms. The first supporting elements are arranged on the outside of the spiral arms.

In one example embodiment of the micromechanical diaphragm system of the present invention, a plurality of spacer elements having a further first supporting element and a further spring element is arranged between the first diaphragm and the second diaphragm. Furthermore, further spacer elements having a first supporting element and a second supporting element are arranged between the first diaphragm and the second diaphragm. The first supporting element of the further spacer elements faces the first diaphragm. The second supporting element of the further spacer elements faces the second diaphragm. The first supporting element and the second supporting element are connected via a spring element. The further spacer elements also respectively have a further second supporting element. The further second supporting element faces the second diaphragm. The further second supporting element is connected to the first supporting element of the further spacer element via a further spring element. The first supporting elements and the further first supporting elements form a first triangular grid. The second supporting elements and the further second supporting elements form a second triangular grid arranged offset to the first triangular grid. Such an arrangement results in low flexural strength.

In one example embodiment of the micromechanical diaphragm system of the present invention, the spacer element furthermore has a further second supporting element. The first supporting element is connected via the spring element to a center element. The further first supporting element is connected via the further spring element to the center element. The center element is connected via a further spring element to the second supporting element. The center element is connected via a further spring element to the further second supporting element. Such a supporting element can result in advantageous flexural strength of the micromechanical diaphragm system.

In one example embodiment of the micromechanical diaphragm system of the present invention, the spring element and the further spring elements of at least one of the spacer elements form a substantially right-angled cross.

In one example embodiment of the micromechanical diaphragm system of the present invention, the spring element and/or the further spring element are designed as a torsion spring. These torsion springs advantageously have a small extent in at least one direction perpendicular to their torsion axis. Torsion springs are simple to produce and make it possible to adjust the flexural strength of the micromechanical diaphragm system in a simple manner.

In one example embodiment of the micromechanical diaphragm system of the present invention, at least one spring element is designed as a folded spring element. A surface required for the spacer element can thereby be reduced.

In one example embodiment of the micromechanical diaphragm system of the present invention, the first supporting element is designed in the form of a contact wall, which may be circular, for example. The spring element is designed as a spring diaphragm.

In one example embodiment of the micromechanical diaphragm system of the present invention, the first diaphragm and the second diaphragm are subdivided into an inner region and an outer region enclosing the inner region. Spacer elements arranged in the outer region contain a spring element. Spacer elements arranged in the inner region are designed as stiffening elements. Bending of the diaphragm can thus be adjusted in a targeted manner.

In one example embodiment of the micromechanical MEMS device of the present invention, the first diaphragm and the second diaphragm are subdivided into an inner region and an outer region enclosing the inner region. Spacer elements which are arranged in the outer region can have a first design, a first surface density, a first orientation of the spring elements, and a first design of the spring elements. Spacer elements which are arranged in the inner region can have a second design, a second surface density, a second orientation of the spring elements, and a second design of the spring elements. In particular, the spring elements can be oriented in an azimuthal direction in an outer region and in a radial direction in an inner region. In particular, a transition between the first and the second region can also be continuous, i.e., the previously listed parameters change continuously or the density of the spacer elements of one and of the other form changes continuously.

In one example embodiment of the micromechanical diaphragm system of the present invention, a closed cavity is arranged between the diaphragms.

In one example embodiment of the micromechanical diaphragm system of the present invention, the cavity has a negative pressure, in particular a vacuum. This can in particular mean that a pressure in the cavity is smaller than a provided ambient pressure. A collapse of the diaphragm system due to the negative pressure in the cavity can be avoided or at least made more difficult by the spacer elements.

In one example embodiment of the micromechanical diaphragm system of the present invention, the second supporting element rests against the second diaphragm due to the negative pressure. Without the negative pressure, the second diaphragm can be spaced apart from the second supporting element. Only by the negative pressure are the diaphragms moved toward one another so far that the second supporting element rests against the second diaphragm.

In one example embodiment of the micromechanical diaphragm system of the present invention, the micromechanical diaphragm system is designed as a microelectromechanical diaphragm system. The first diaphragm has a first diaphragm electrode. The second diaphragm has a second diaphragm electrode. Furthermore, a central support structure having at least one center electrode is arranged between the first diaphragm and the second diaphragm. The center electrode has through-openings. The spacer elements are arranged in the through-openings. When the diaphragms are deflected in a vertical movement direction, a change in capacitance between the first diaphragm electrode and the center electrode or the second diaphragm electrode and the center electrode can be sensed and evaluated. Furthermore, a voltage can instead be applied between the first diaphragm electrode and the center electrode or the second diaphragm electrode and the center electrode in order to achieve a deflection of the microelectromechanical diaphragm system.

Furthermore, stiffening elements can be arranged in the through-openings.

In one example embodiment of the micromechanical diaphragm system of the present invention, the central support structure and the spacer elements consist at least partially of the same material. If present, the stiffening elements can also consist of this material.

The present invention furthermore relates to a micromechanical component for interacting with a pressure gradient of a fluid, which has a substrate having a through-cavity and a micromechanical diaphragm system according to the present invention. The micromechanical diaphragm system at least partially spans the through-cavity. Such a micromechanical component can be a microelectromechanical component, in particular a microelectromechanical acoustic component, such as a microphone or a loudspeaker or else a pressure sensor.

The present invention furthermore relates to a method for producing a micromechanical diaphragm system according to the present invention. In this method, the steps explained below are carried out. First, a first diaphragm layer is applied and structured. A first sacrificial layer is subsequently applied to the first diaphragm layer and structured. A spring element layer is now applied to the first sacrificial layer and structured. A second sacrificial layer is subsequently applied to the spring element layer and structured. A second diaphragm layer is subsequently applied to the second sacrificial layer and structured. The sacrificial layers are then removed.

Exemplary embodiments of the present invention are explained with reference to the figures.

### BRIEF DESCRIPTION OF THE DRAWINGS

FIG. 1 shows a cross-section through a micromechanical diaphragm system according to an example embodiment of the present invention.

FIG. 2 shows a further cross-section through the micromechanical diaphragm system of FIG. 1 according to an example embodiment of the present invention.

FIG. 3 shows a cross-section of a micromechanical component having a micromechanical diaphragm system of FIGS. 1 and 2 according to an example embodiment of the present invention.

FIG. 4 shows a perspective view of a first diaphragm and of two spacer elements of a micromechanical diaphragm system according to an example embodiment of the present invention.

FIG. 5 shows a perspective view of a further first diaphragm and of a further spacer element of a further micromechanical diaphragm system according to an example embodiment of the present invention.

FIG. 6 shows a perspective view of a further first diaphragm and of a further spacer element as well as details of further spacer elements of a further micromechanical diaphragm system according to an example embodiment of the present invention.

FIG. 7 shows a perspective view of a further first diaphragm and of further spacer elements of a further micromechanical diaphragm system according to an example embodiment of the present invention.

FIG. 8 shows a perspective view of a further first diaphragm and of further spacer elements of a further micromechanical diaphragm system according to an example embodiment of the present invention.

FIG. 9 shows a perspective view of a further first diaphragm and of further spacer elements of a further micromechanical diaphragm system according to an example embodiment of the present invention.

FIG. 10 shows a detail of the perspective view of the further micromechanical diaphragm system of FIG. 9 according to an example embodiment of the present invention.

FIG. 11 shows a perspective view of a further first diaphragm and of a further spacer element of a further micromechanical diaphragm system according to an example embodiment of the present invention.

FIG. 12 shows a plan view of a further first diaphragm and of a further spacer element of a further micromechanical diaphragm system according to an example embodiment of the present invention.

FIG. 13 shows a cross-section of a further micromechanical diaphragm system according to an example embodiment of the present invention.

FIG. 14 shows a plan view of a further first diaphragm and of a further spacer element of the further micromechanical diaphragm system of FIG. 13 according to an example embodiment of the present invention.

FIG. 15 shows a cross-section of a further micromechanical diaphragm system according to an example embodiment of the present invention.

FIG. 16 shows a cross-section of a further micromechanical diaphragm system according to an example embodiment of the present invention.

FIG. 17 shows a sectional perspective view of a further first diaphragm and of further spacer elements of a further micromechanical diaphragm system according to an example embodiment of the present invention.

FIG. 18 shows a flowchart of a production method for a micromechanical diaphragm system according to an example embodiment of the present invention.

### DETAILED DESCRIPTION OF EXAMPLE EMBODIMENTS

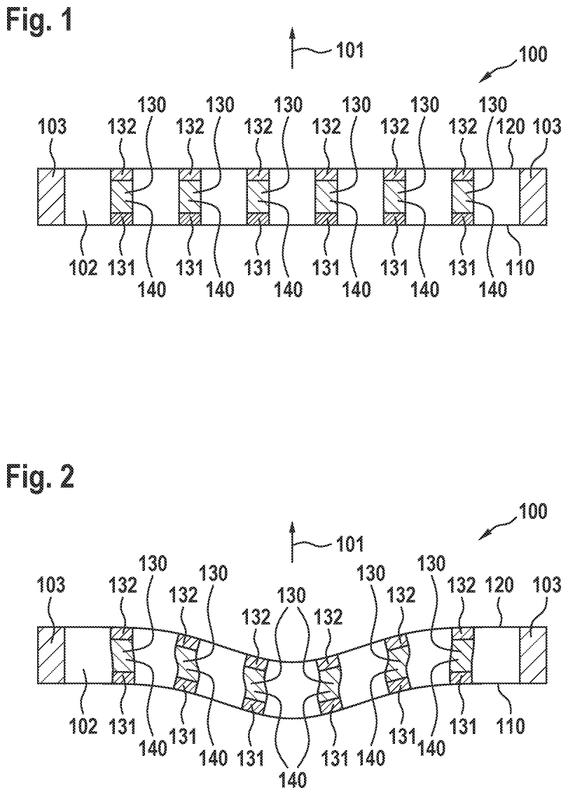

FIG. 1 shows a cross-section through a micromechanical diaphragm system 100. The micromechanical diaphragm system 100 has a first diaphragm 110 and a second diaphragm 120 and spacer elements 130 arranged between the first diaphragm 120 and the second diaphragm. At least one of the spacer elements 130 has a first supporting element 131 and a second supporting element 132. The first supporting element 131 faces the first diaphragm 110. The second supporting element 132 faces the second diaphragm 120. The first supporting element 131 and the second supporting element 132 are connected via a spring element 140. In the exemplary embodiment of FIG. 1, the first supporting element 131 adjoins the first diaphragm 110. The second supporting element 132 adjoins the second diaphragm 120.

A mobility of the first supporting element 131 relative to the second supporting element 132 can be achieved by the spring element 140. A flexural strength of the micromechanical diaphragm system 100 can thereby be reduced since the bending-induced different movements of the diaphragms 110, 120 relative to one another can be compensated by the spring element 140. Such a bending can, for example, occur when the micromechanical diaphragm system 100 is deflected in a vertical movement direction 101. Such a micromechanical diaphragm system 100 thus has less flexural strength than the diaphragm systems from the related art. As a result, more sensitive microphones having the same area or smaller microphones having the same sensitivity are possible, for example.

The diaphragms 110, 120 can be arranged substantially in parallel. This can mean that an angle between the main extension planes of the diaphragms 110, 120 is less than 5 degrees, in particular less than 2 degrees, and preferably 0. The main extension planes of the diaphragms 110, 120 can be arranged substantially perpendicularly to the vertical movement direction 101. The diaphragms 110, 120 are preferably arranged perpendicularly to the vertical movement direction 101.

It can be provided that a plurality of spacer elements 130 is designed in such a way that they each have a first supporting element 131 and a second supporting element 132, the first supporting element 131 in each case faces the first diaphragm 110 and the second supporting element 132 in each case faces the second diaphragm 120, and the first supporting element 131 and the second supporting element 132 are in each case connected via a spring element 140. In FIG. 1, all spacer elements 130 are shown designed in this way.

Furthermore, FIG. 1 shows, as an optional exemplary embodiment of the micromechanical diaphragm system 100, that a closed cavity 102 is arranged between the diaphragms 110, 120. On the outside, the diaphragms 110, 120 are connected to one another by an optional edge element 103. It can in particular be provided that the closed cavity 102 does not exchange fluids with an environment of the micromechanical diaphragm system 100.

In one exemplary embodiment of the micromechanical diaphragm system 100, the cavity 102 has a negative pressure, in particular a vacuum. This can in particular mean that a pressure in the cavity 102 is smaller than a provided ambient pressure. A collapse of the diaphragm system 100 due to the negative pressure in the cavity 102 can be avoided or at least made more difficult by the spacer elements 130.

A thickness of the first diaphragm 110, with respect to the vertical movement direction 101, can be at least 150 nanometers and at most 5 micrometers. Alternatively or additionally, a thickness of the first diaphragm 120, with respect to the vertical movement direction 103, can be at least 150 nanometers and at most 5 micrometers. A distance of the first diaphragm 110 from the second diaphragm 120 can be at least 0.5 micrometers and at most 18 micrometers.

FIG. 2 shows a further cross-section through the micromechanical diaphragm system 100 of FIG. 1 after a deflection of the micromechanical diaphragm system 100 in the vertical movement direction 101. The diaphragms 110, 120 are now deflected in parallel. If the spacer elements 130 do not have any spring elements 140, a counteracting stress occurs in curved regions of the diaphragms 110, 120 since the diaphragms 110, 120 would actually have to be displaced laterally relative to one another due to the curvature but are prevented from doing so by rigid spacer elements. As a result of the spring elements 140 of the spacer elements 130, the first supporting element 131 can move relative to the second supporting element 132 so that the diaphragms 110, 120 can also be displaced relative to one another as a result and less counteracting stress is thus present in the micromechanical diaphragm system 100.

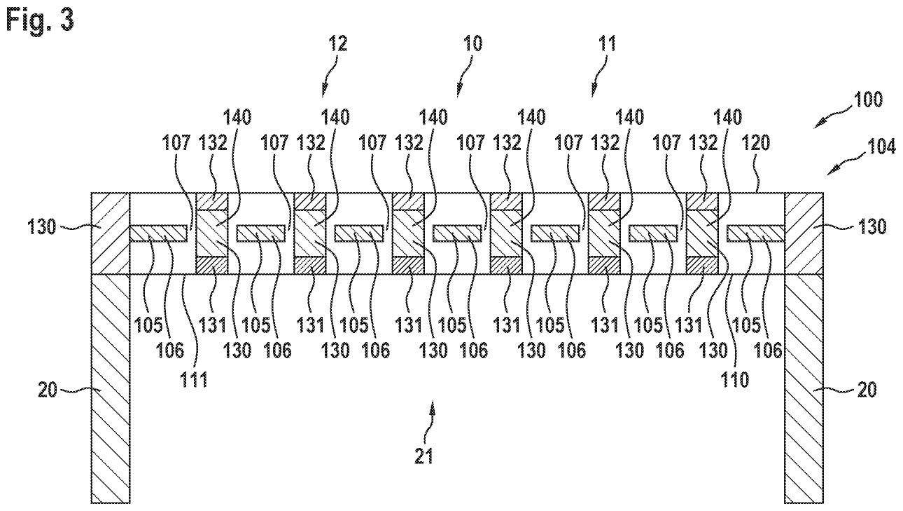

FIG. 3 shows a cross-section of a micromechanical component 10 for interacting with a pressure gradient of a fluid. The micromechanical component 10 has a micromechanical diaphragm system 100 and a substrate 20 having a through-cavity 21. The micromechanical diaphragm system 100 spans the through-cavity 21 at least partially, completely in the exemplary embodiment shown in FIG. 3. The micromechanical diaphragm system 100 is constructed as shown in FIGS. 1 and 2 and in particular has the spacer elements 130, shown in FIGS. 1 and 2, having spring elements 140. The first diaphragm 110 faces the through-cavity 21. The edge elements 103 of the micromechanical diaphragm system 100 lie on the substrate 21 and are arranged outside the through-cavity.

In the exemplary embodiment of FIG. 3, the micromechanical diaphragm system 100 is designed as a microelectromechanical diaphragm system 104. The first diaphragm 110 has a first diaphragm electrode 111. The second diaphragm 120 has a second diaphragm electrode 121. Furthermore, a central support structure 105 having at least one center electrode 106 is arranged between the first diaphragm 110 and the second diaphragm 120. The central support structure 105 and the center electrode 106 have through-openings 107. The spacer elements 130 are arranged in the through-openings 107 or extend through the through-openings 107. When the diaphragms 110, 120 are deflected in the vertical movement direction 101, a change in capacitance between the first diaphragm electrode 111 and the center electrode 106 or the second diaphragm electrode 121 and the center electrode(s) 106 can be sensed and evaluated. Furthermore, an electrical voltage can instead be applied between the first diaphragm electrode 111 and the center electrode 106 or the second diaphragm electrode 121 and the center electrode 106 in order to achieve a deflection of the microelectromechanical diaphragm system 104. Outside the image plane of FIG. 3, the center electrode 106 can connect the portions of the center electrode 106 shown in FIG. 3, which are interrupted due to the through-openings 107, to one another.

A micromechanical component 10 having a microelectromechanical diaphragm system 104 can be referred to as a microelectromechanical component 11. If a sound is to be generated or detected by means of the microelectromechanical component 11, the microelectromechanical component 11 can be referred to as a microelectromechanical acoustic component 12 and can, for example, be designed as a microphone or a loudspeaker. In the case of the microphone, a sound impinging on the microelectromechanical diaphragm system 104 can result in a deflection of the microelectromechanical diaphragm system 104, which can then be detected as a change in capacitance between the first diaphragm electrode 111 and the center electrode 106 or the second diaphragm electrode 121 and the center electrode 106. In the case of the loudspeaker, a voltage applied between the first diaphragm electrode 111 and the center electrode 106 or the second diaphragm electrode 121 and the center electrode 106 can result in a deflection of the microelectromechanical diaphragm system 104, which can be emitted as a sound.

Alternatively, however, the microelectromechanical component 11 may also be a pressure sensor. In this case, a pressure difference between the through-cavity 21 and a region outside the through-cavity 21 can lead to a deflection of the microelectromechanical diaphragm system 104, which can then be detected via a change in capacitance between the first diaphragm electrode 111 and the center electrode 106 or the second diaphragm electrode 121 and the center electrode 106.

Furthermore, optional stiffening elements, not shown in FIG. 3, can be arranged in the through-openings 107.

In one exemplary embodiment of the micromechanical diaphragm system 100, 104, the central support structure 105 and the spacer elements 130 consist at least partially of the same material. If present, the stiffening elements can also consist of this material. This makes possible a simple production method in which the central support structure 105 and the spacer elements 130 can be produced in a layer deposition process.

The first diaphragm electrode 111 and/or the second diaphragm electrode 121 and/or the center electrode 106 can comprise doped polysilicon or consist of doped polysilicon.

A distance of the first diaphragm 110 to the center electrode 106, with respect to the vertical movement direction 101, can be at least 300 nanometers and at most 5 micrometers. Alternatively or additionally, a distance of the second diaphragm 120 to the center electrode 106, with respect to the vertical movement direction 101, can be at least 300 nanometers and at most 5 micrometers. Alternatively or additionally, a thickness of the center electrode 106, with respect to the vertical movement direction 101, can be at least 500 nanometers and at most 18 micrometers.

The spring elements 140 shown in FIGS. 1 to 3 are movable perpendicularly to the vertical movement direction 101 in at least one lateral direction. The first supporting element 131 and the second supporting element 132 are arranged linearly with the spring element 140. In particular, a connecting line extending through the first supporting element 131 and the second supporting element 132 is parallel to the first vertical movement direction 101 and/or perpendicular to the main extension plane of the diaphragms 110, 120. However, it is also possible to use spring elements 140 in which different directions perpendicular to the vertical movement direction 101 have different flexural strengths. With such spring elements 140, a flexural strength of the micromechanical diaphragm system 100 can be adjusted in different directions. In the following figures, various configurations of the spacer element 130 are described, wherein the second diaphragm 120 and a support structure 105 having center electrode 106 are optionally omitted in order to increase clarity.

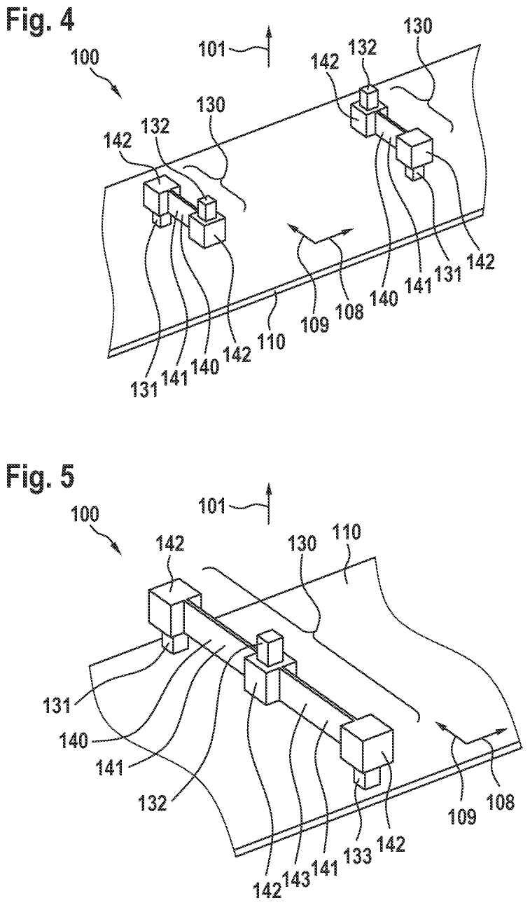

FIG. 4 shows a perspective view of a first diaphragm 110 and of two spacer elements 130 of a micromechanical diaphragm system 100. The second diaphragm 120 is not shown but can be arranged parallel to the first diaphragm 110 and can rest on the second supporting elements 132 of the spacer elements. In this exemplary embodiment, the first supporting elements 131 and the second supporting elements 132 of the spacer elements 130 are in each case offset to one another. This can in particular mean that the first supporting element 131 and the second supporting element 132 are not arranged linearly with the spring element 140. In particular, a connecting line extending through the first supporting element 131 and the second supporting element 132 is in this case neither parallel to the first vertical movement direction 101 nor perpendicular to the main extension plane of the diaphragms 110, 120.

The diaphragms 110, 120 are parallel to a first extension direction 108 and a second extension direction 109. The first extension direction 108, the second extension direction 109, and the vertical movement direction 101 can form a Cartesian or a cylindrical coordinate system.

The spring elements 140 are oriented in the second extension direction 109. A flexural strength of the micromechanical diaphragm system 100 can thereby be provided in the second extension direction 109. In the second extension direction 109, such spacer elements 130 thus act like conventional spacer elements without a spring element, thus having a stiffening effect. In contrast, the flexural strength in the first extension direction 108 is significantly reduced so that a bending of the micromechanical diaphragm system 100 in the first extension direction 108 is facilitated.

In the exemplary embodiment of the micromechanical diaphragm system 100 of FIG. 3, the spring elements 140 are designed as a torsion spring 141. Torsion springs 141 are simple to produce and make it possible to adjust the flexural strength of the micromechanical diaphragm system 100 in a simple manner. In a partial region, a torsion spring 141 can have a height which is greater than a width, or in particular a height which is at least twice as large as its width. The height of the torsion spring 141 is here parallel to the vertical movement direction 101, while the width is parallel to the first extension direction 108. The torsion spring 141 can preferably be oriented perpendicularly to the direction in which a low flexural strength of the micromechanical diaphragm system 100 is provided. A spring element 140 is preferably used, the height of which with respect to the vertical movement direction 101 is greater than a width in the first extension direction 108, and the length of which with respect to the second extension direction 109 is greater than the width by at least a factor of two, in particular by a factor of five.

The spacer elements 130 of FIG. 3 are furthermore optionally designed in such a way that the first supporting element 131 of the one spacer element 130 and the second supporting element 132 of the other spacer element 130 lie in a line with respect to the first extension direction 108. The same applies to the respective other supporting elements 132, 131.

In the exemplary embodiment of FIG. 4, optional spring fastening elements 142 are also shown, which are arranged between the supporting elements 131, 132 and the spring elements 140. They can be used for a simplified production of the spacer elements 130 since a simpler attachment of the supporting elements 131, 132 to the spring elements 140 is thus possible. In particular, with respect to the first extension direction 108 and the second extension direction 109, the spring fastening elements 142 can have a greater dimension than the supporting elements 131, 132.

It can be provided that a plurality of the spacer elements 130 of the micromechanical diaphragm systems 100 of FIGS. 1 to 3 is designed analogously to the spacer element 130 of FIG. 4. In particular, all spacer elements 130 of the micromechanical diaphragm systems 100 of FIGS. 1 to 3 can be designed analogously to the spacer element 130 of FIG. 4.

FIG. 5 shows a perspective view of a first diaphragm 110 and of a spacer element 130 of a micromechanical diaphragm system 100. The spacer element 130 can correspond to the spacer elements 130 of FIG. 4 except where differences are described below. The spacer element 130 has a further first supporting element 133. The further first supporting element 133 and the second supporting element 132 are connected via a further spring element 143. This configuration makes it possible to design the spacer element 130 to be more stable, thus making a collapse of the micromechanical diaphragm system 100 more unlikely or preventing it. In particular, a force acting parallel to the vertical movement direction 101 on the diaphragms 110, 120, which force may, for example, be caused by the negative pressure in the cavities 102, can be better supported with the spacer element 130 of FIG. 5 than with the spacer elements 130 of FIG. 4. Analogously to FIG. 4, a spacer element 130 as shown in FIG. 5 acts in the second extension direction 109 like a conventional spacer element without a spring element. In contrast, the flexural strength in the first extension direction 108 is significantly reduced so that a bending of the micromechanical diaphragm system 100 in the first extension direction 108 is facilitated.

In the exemplary embodiment of FIG. 5, the optional spring fastening elements 142 are also provided, wherein a spring fastening element 142 is in each case arranged between all spring elements 140, 143 and between all supporting elements 131, 132, 133. Furthermore, it is optionally shown in FIG. 5 that the spring elements 140, 143 are arranged linearly. Furthermore, the spring elements 140, 143 extend in the second extension direction 109. Furthermore, both spring elements 140, 143 are optionally designed as torsion springs 141.

It can be provided that a plurality of the spacer elements 130 of the micromechanical diaphragm systems 100 of FIGS. 1 to 3 is designed analogously to the spacer element 130 of FIG. 5. In particular, all spacer elements 130 of the micromechanical diaphragm systems 100 of FIGS. 1 to 3 can be designed analogously to the spacer element 130 of FIG. 5.

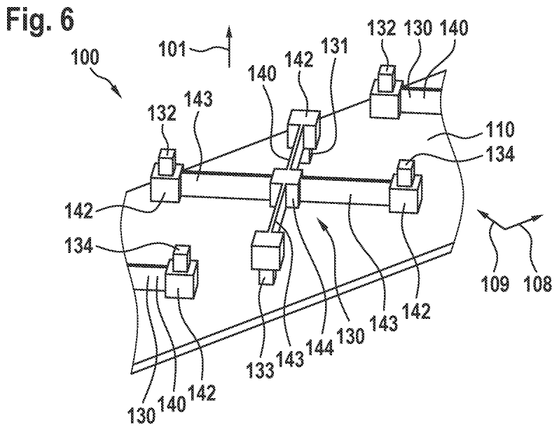

FIG. 6 shows a perspective view of a further first diaphragm 110 and of a further spacer element 130 as well as details of further spacer elements 130 of a further micromechanical diaphragm system 100. The spacer element 130 can correspond to the spacer elements 130 of FIG. 4 except where differences are described below. The spacer element 130 in particular has the further first supporting element 133 and the further spring element 143 between the further first supporting element 133 and the second supporting element 132. The spacer element 130 furthermore has a further second supporting element 134. The first supporting element 131 is connected via the spring element 140 to an optional center element 144. The further first supporting element 133 is connected via the further spring element 143 to the optional center element 144. The optional center element 144 is connected via a further spring element 143 to the second supporting element 132. The optional center element 144 is connected via a further spring element 143 to the further second supporting element 134. In particular, the first supporting element 131 is thus connected to the second supporting element 132 via the spring element 140 but also via the optional center element 144 and a further spring element 143. Such a supporting element 130 can result in an advantageous flexural strength of the micromechanical diaphragm system 100. In particular, a connecting line between the first supporting element 131 and the further first supporting element 133 is linearly independent of a connecting line between the second supporting element 132 and the further second supporting element 134. In this context, linearly independent can in particular mean non-parallel. The optional center element 144 is furthermore optionally arranged in such a way that the connecting line between the first supporting element 131 and the further first supporting element 133 extends via the optional center element 144, and the connecting line between the second supporting element 132 and the further second supporting element 134 likewise extends via the optional center element 144. A cross-shaped spacer element 130 thus results.

In one exemplary embodiment of the micromechanical diaphragm system 100, the spring elements 140, 143 of at least one of the spacer elements 130 form a right-angled cross. Such a configuration is likewise optionally shown in FIG. 6.

The spacer element 130 shown in FIG. 6 in particular makes possible identical flexural strengths in the first extension direction 108 and the second extension direction 109, this being achieved by the right-angled arrangement of the spring elements 140, 143. If the spring elements 140, 143 form a non-right-angled cross, any ratio of the flexural strengths in the first extension direction 108 and the second extension direction 109 can be adjusted.

In the spacer element shown in FIG. 6, both the connecting line between the first supporting element 131 and the further first supporting element 133 and the connecting line between the second supporting element 132 and the further second supporting element 134 are optionally arranged obliquely to the first extension direction 108 or to the second extension direction 109, in particular at a 45-degree angle.

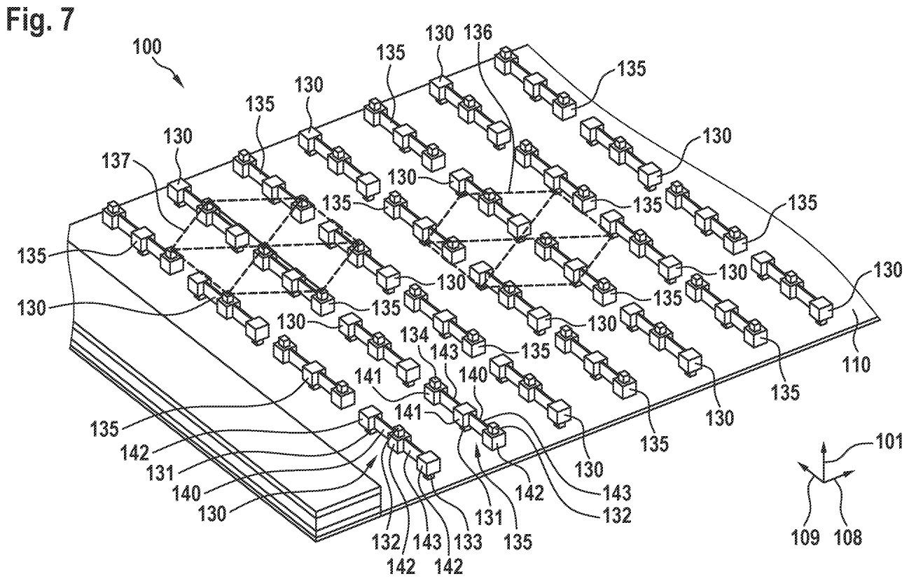

FIG. 7 shows a perspective view of a further first diaphragm 110 and of a plurality of spacer elements 130 of a further micromechanical diaphragm system 100. The spacer element 130 can correspond to the spacer element 130 of FIG. 5 except where differences are described below. In particular, a plurality of spacer elements 130 having a first supporting element 131 and a second supporting element 132 having a spring element 140 arranged therebetween, and a further first supporting element 133 and a further spring element 143 arranged between the further first supporting element 133 and the second supporting element 132 is arranged between the first diaphragm 110 and the second diaphragm 120 (again not shown in FIG. 7). Furthermore, further spacer elements 135 having a first supporting element 131 and a second supporting element 132 are arranged between the first diaphragm 110 and the second diaphragm 120. The first supporting element 131 of the further spacer elements 135 faces the first diaphragm 110. The second supporting element 132 of the further spacer elements 135 faces the second diaphragm 120. The first supporting element 131 and the second supporting element 132 are connected via a spring element 140. The further spacer elements 135 also respectively have a further second supporting element 134. The further second supporting element 134 faces the second diaphragm 120. The further second supporting element 134 is connected to the first supporting element 131 of the further spacer element 135 via a further spring element 143. In order to increase clarity, reference signs for all features associated with the spacer elements 130, 135 are shown in each case only for one spacer element 130 and one further spacer element 135. In particular, all spacer elements 130 have the two first supporting elements 131, 133, and all further spacer elements 135 have the second supporting elements 132, 134. The supporting elements 131, 132, 133 of the spacer elements 130 are respectively arranged in a line. The supporting elements 131, 132, 134 of the further spacer elements 135 are likewise arranged in a line.

The first supporting elements 131 and the further first supporting elements 133 form a first triangular grid 136. The second supporting elements 132 and the further second supporting elements 134 form a second triangular grid 137 arranged offset to the first triangular grid 136. Such an arrangement results in a low flexural strength in the first extension direction 108, while the arrangement has a high flexural strength in the second extension direction 109. In addition, the arrangement of the spacer elements 130, 135 is particularly robust to a collapse of the micromechanical diaphragm system 100. The spacer elements 130 optionally likewise have the spring fastening elements 142.

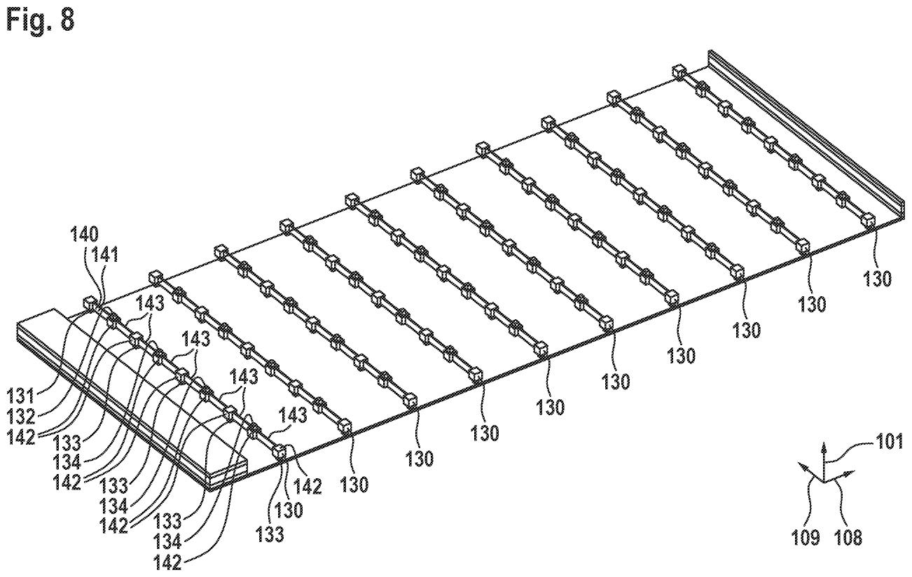

FIG. 8 shows a perspective view of a further first diaphragm 110 and of a plurality of spacer elements 130 of a further micromechanical diaphragm system 100. The spacer elements 130 can correspond to the spacer element 130 of FIG. 5 except where differences are described below. In addition to the first supporting element 131, the second supporting element 132, and the further first supporting element 133, and the spring element 140 located therebetween, and the further spring element 143 located therebetween, the spacer elements 130 have further second supporting elements 134 and further first supporting elements 133 having further spring elements 143 located therebetween. The supporting elements 131, 132, 133, 134 of each spacer element 130 are respectively arranged in a line, as are the spring elements 140, 143 of each spacer element 130. In this case, further first supporting elements 133 and further second supporting elements 134 are always arranged alternately. The spacer elements are oriented in the second extension direction 109 so that a high flexural strength in the second extension direction 109 and a low flexural strength in the first extension direction 108 result.

In order to increase clarity, reference signs for all features associated with the spacer element 130 are shown in FIG. 8 only for one spacer element 130. The spacer elements 130 optionally likewise have the spring fastening elements 142.

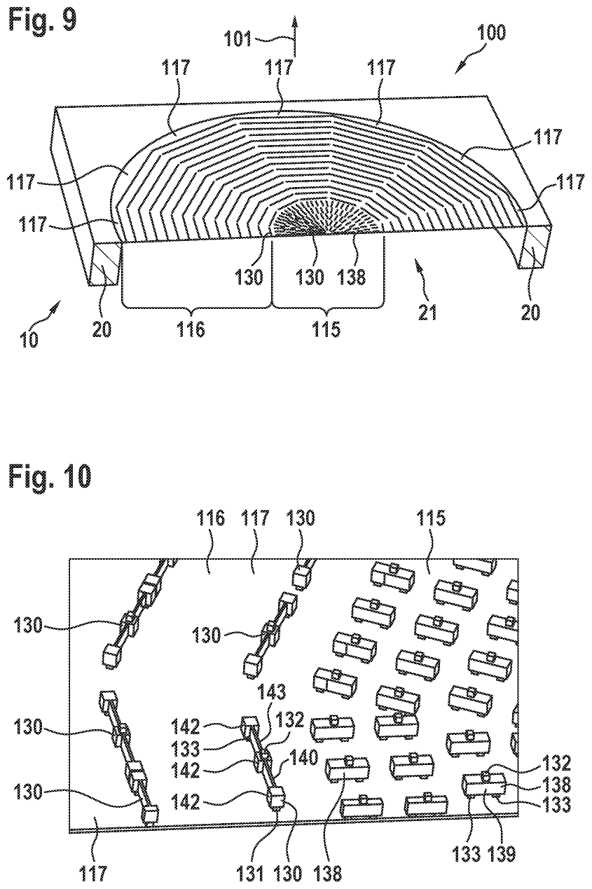

FIG. 9 shows a sectional perspective view of a further first diaphragm 110 and of spacer elements 130 of a further micromechanical diaphragm system 100. Furthermore, a substrate 20 having a through-cavity 21, which is spanned by the first diaphragm 110, is also shown here. The second diaphragm 120 and an optional support structure 105 having a center electrode 106 are again not shown. A micromechanical component 10 would result with the second diaphragm 120.

The first diaphragm 110 and the second diaphragm 120, and thus also the micromechanical diaphragm system 100, are divided into an inner region 115 and an outer region 116. The outer region 116 encloses the inner region 115. A plurality of spacer elements 130 is arranged both in the inner region 115 and in the outer region 116. In the outer region 116, spacer elements 130 having spring elements 140 are arranged substantially in an azimuthal orientation, which elements may be designed as explained in connection with FIGS. 1 to 8. In the inner region 115, the spacer elements 130 are designed in a substantially radial orientation as stiffening elements 138. A micromechanical diaphragm system 100 can thereby be provided, which has no or only a slight curvature in the inner region 115 when the diaphragms 110, 120 and thus the micromechanical diaphragm system 100 are deflected in the vertical movement direction 101. Instead, the spacer elements 130 having spring elements 140 in the outer region 116 make a corresponding bending of the diaphragms 110, 120 and thus of the micromechanical diaphragm system 100 possible here.

In order to increase the clarity of FIG. 9, not all spacer elements 130 are provided with a reference sign. The stiffening elements 138 can consist of the same material and the same basic structure as the spacer elements 130 having spring elements 140. However, they differ in orientation and in the design of the spring elements 140.

FIG. 10 shows a detailed view of the first diaphragm 110 of the micromechanical diaphragm system 100 of FIG. 9. It can be seen here that the spacer elements 130 in the outer region 116 are constructed analogously to the spacer element 130 of FIG. 5 and have a first supporting element 131, a second supporting element 132, and a further first supporting element 133 having spring elements 140, 143 arranged therebetween. In order to increase the clarity of FIG. 10, not all spacer elements 130 are provided with a reference sign and reference signs for the further features are not shown for all spacer elements 130.

In one exemplary embodiment of the micromechanical diaphragm system 100, the inner region 115 is circular and the outer region 116 is arranged annularly around the inner region 115. The spacer elements 130 having spring elements 140 in the outer region 116 are respectively arranged parallel to a tangent to an enclosing circle of the inner region 115. Furthermore, the outer region 116 is subdivided into sectors 117, wherein FIG. 9 shows that the outer region 116 comprises twelve sectors 117. However, a different number of sectors 117 may also be provided. In each sector 117, the spacer elements 130 are arranged parallel to one another. This achieves a low flexural strength in the direction that makes the greatest possible deflection of the inner region 115 possible.

In the representation of FIGS. 9 and 10, the spacer elements 130 in the outer region are shown analogously to FIG. 5. However, the other configurations may also be selected. In particular, the spacer elements 130 of FIG. 8 can be used, wherein the number of supporting elements 131, 132, 133, 134 for the spacer elements 130 of a sector 117 can increase outward.

The stiffening elements 138 can likewise have a first supporting element 131, a second supporting element 132, and a further first supporting element 133, which are connected via a stiffening beam 139. In particular, the stiffening beam allows no movement or a movement as small as possible of the second supporting element 132 relative to the first supporting element 131 or further first supporting element 133. The stiffening beams 139 can in particular be significantly wider and shorter than the spring elements 140 and thus fix the supporting elements 131, 132, 133 rigidly to one another.

In one exemplary embodiment of the micromechanical diaphragm system, the spring element 140 and/or the further spring element 143 are designed as a torsion spring 141. Torsion springs 141 are simple to produce and make it possible to adjust the flexural strength of the micromechanical diaphragm system 100 in a simple manner. In the configurations of FIGS. 4 to 10, the spring elements 140 and the further spring elements 143 are shown as torsion springs 141.

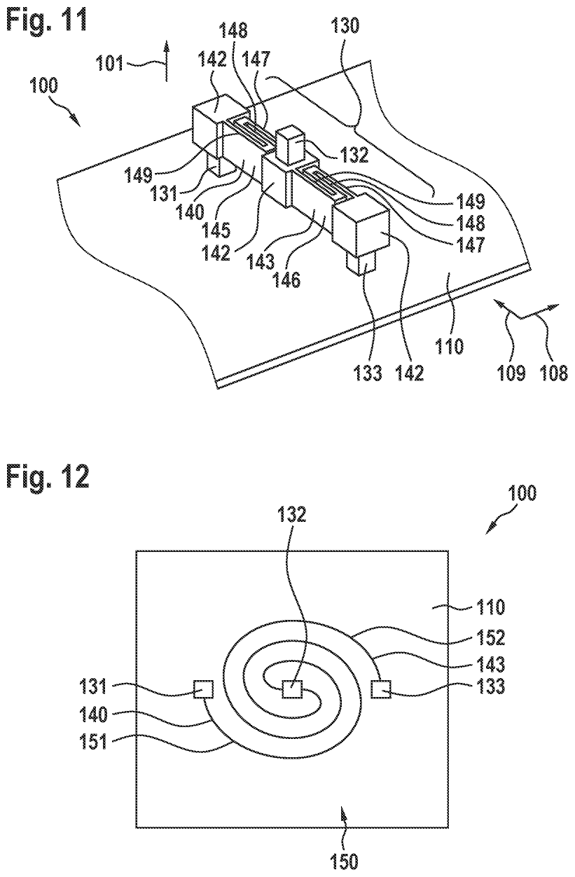

FIG. 11 shows a perspective view of a first diaphragm 110 and of a spacer element 130 of a micromechanical diaphragm system 100. The spacer element 130 can correspond to the spacer elements 130 of FIG. 5 except where differences are described below. The spring element 140 is designed as a folded spring element 145. The further spring element 143 is designed as a further folded Spring element 146. Folded spring elements 145, 146 respectively have a first portion 147 which extends in the second extension direction 109. The first portion 147 is connected to a second portion 148, which extends antiparallel to the first portion 147 and thus runs opposite to the second extension direction 109. The second portion 148 is connected to a third portion 149, which extends antiparallel to the second portion 148 and thus parallel to the first portion 147 and again runs in the direction of the second extension direction 109. A surface required for the spacer element 130 can thereby be reduced.

FIG. 12 shows a plan view of a first diaphragm 110 and of a spacer element 130 of a micromechanical diaphragm system 100. In this exemplary embodiment of the micromechanical diaphragm system 100, a first supporting element 131, a second supporting element 132, and a further first supporting element 133, and a spring element 140 arranged between the first supporting element 131 and the second supporting element 132, and a further spring element 143 arranged between the further first supporting element 133 and the second supporting element 132 are provided again. The spring element 140 and the further spring element 143 form a double spiral 150 consisting of a spiral arm 151 and a further spiral arm 152. The spring element 140 is formed by the spiral arm 151; the further spring element 143 is formed by the further spiral arm 152. The second supporting element 132 is arranged between the spiral arms 151, 152. The first supporting elements 131, 132 are arranged on the outside of the spiral arms 151, 152.

The double spiral 150 can in particular be an Archimedean double spiral. The spiral arm 151 can in particular be an Archimedean spiral arm. The further spiral arm 152 can in particular be a further Archimedean spiral arm.

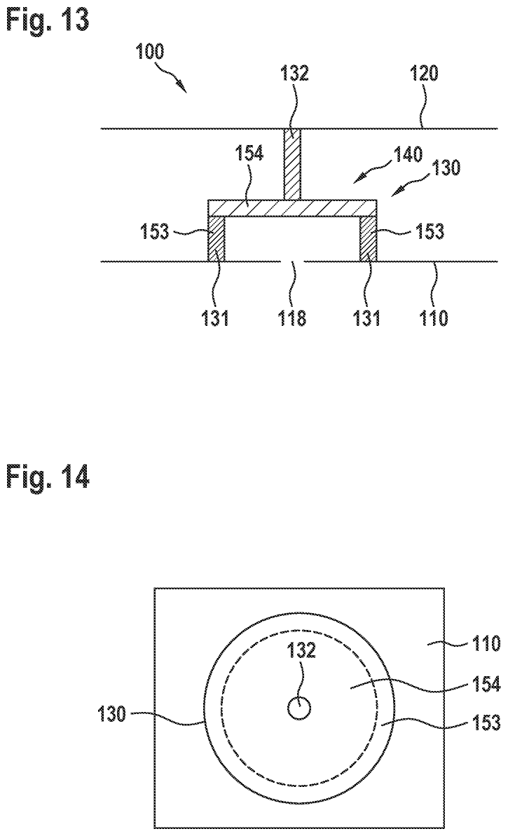

FIG. 13 shows a cross-section of a further micromechanical diaphragm system 100, in which a spacer element 130 is arranged between two diaphragms 110, 120. The spacer element 130 has a first supporting element 131 and a second supporting element 132. The first supporting element 131 faces the first diaphragm 110. The second supporting element 132 faces the second diaphragm 120. The first supporting element 131 and the second supporting element 132 are connected via a spring element 140. The first supporting element 131 is designed in the form of a contact wall 153. The contact wall 153 may, for example, be circular. The spring element 140 is designed as a spring diaphragm 154. Optionally, FIG. 13 shows that the first diaphragm 110 may have a first diaphragm opening 118. The first diaphragm opening 118 can be helpful in the production of such a spacer element 130 in order to be able to expose a region between the first diaphragm 110 and the spring diaphragm 154. In this exemplary embodiment as well, the first supporting element 131 and the second supporting element 132 are arranged offset to one another.

FIG. 14 shows a plan view of the first diaphragm 110 and of the spacer element 130 of the micromechanical diaphragm system 100 of FIG. 13. Here, the circular configuration of the contact wall 153 and thus also of the spring diaphragm 154 becomes clear.

However, the contact wall 153 may also have a different shape and may be closed.

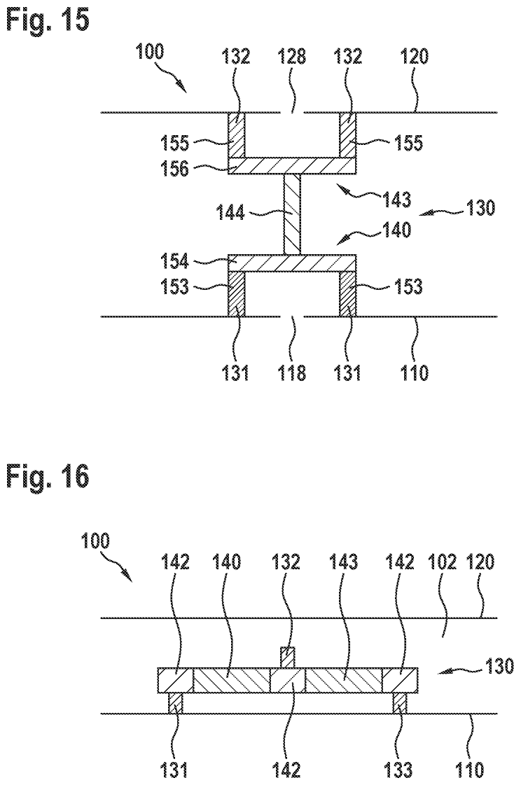

FIG. 15 shows a cross-section of a further micromechanical diaphragm system 100, which corresponds to the diaphragm system of FIGS. 13 and 14 except where differences are described below. The second supporting element 132 is designed as a further contact wall 155. Furthermore, a further spring element 143 is provided which is connected via a center element 144 to the spring element 140 designed as a spring diaphragm 154. The further spring element 143 is designed as a further spring diaphragm 156. Optionally, FIG. 15 shows that the second diaphragm 120 can have a second diaphragm opening 128. The second diaphragm opening 128 can be helpful in the production of such a spacer element 130 in order to be able to expose a region between the second diaphragm 120 and the further spring diaphragm 156.

FIG. 16 shows a cross-section of a micromechanical diaphragm system 100, in which a spacer element 130 designed analogously to FIG. 5 is arranged between two diaphragms 110, 120. However, alternatively, one of the other exemplary embodiments of the spacer element 130 may also be provided. The first supporting element 131 and the further first supporting element 133 adjoin the first diaphragm 110. The second diaphragm 120 is spaced apart from the second supporting element 132. If a negative pressure relative to an external ambient pressure now prevails in the cavity 102, the diaphragms 110, 120 move toward one another. Only by the negative pressure are the diaphragms 110, 120 moved toward one another so far that the second supporting element 132 rests against the second diaphragm 120. Alternatively, it may also be provided that the second supporting element 132 adjoins the second diaphragm 120 and the first supporting elements 131, 133 are arranged spaced apart from the first diaphragm 110. It can be provided that alternative analogous configurations with a mechanical separation of the force path are realized by the spacer elements 130 between the two diaphragms 110, 120. For example, it is possible for one of the supporting elements 131, 133, 132 to be connected to a diaphragm 110, 120 instead of the spring fastening point 142 and to be pressed onto the spring fastening point 142 only by external pressure.

In all shown exemplary embodiments for the micromechanical diaphragm structure 100, it can be provided that the latter is designed as a microelectromechanical diaphragm structure 104 analogously to FIG. 3. In all these cases, it can be provided that all spacer elements 130 of the microelectromechanical diaphragm structure 104 are arranged in through-openings 107 of a support structure 105 and a center electrode 106. In particular in the representations of FIGS. 4 to 14, it becomes clear that the spacer elements can always be enclosed by a support structure 105, optionally having a center electrode 106.

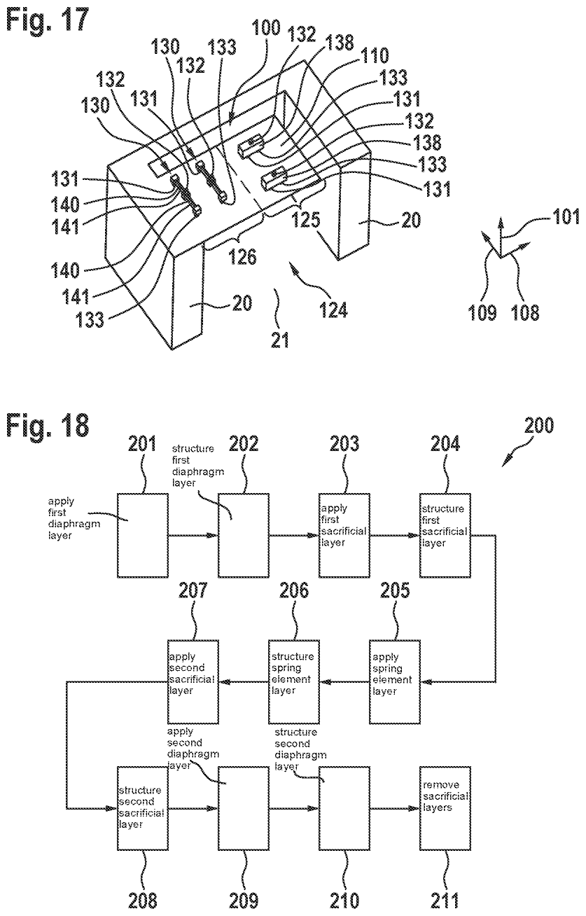

FIG. 17 shows a sectional perspective view of a further first diaphragm 110 and of spacer elements 130 of a further micromechanical diaphragm system 100. In this exemplary embodiment, the first diaphragm 110 is designed as a bending beam 124 suspended on one side. Furthermore, an optional substrate 20 having a through-cavity 21, which is spanned at least partially by the first diaphragm 110, is also shown here. Spacer elements 130 are again arranged on the first diaphragm 110, wherein at least one spacer element 130 has a spring element 140 analogous to the already described spring elements 140. An optional support structure 105 having center electrode 106 and the optional edge elements 103 of the cavity 102 are again not shown but can be provided analogously to FIGS. 1 to 3. The second diaphragm 120 is likewise not shown but is arranged above the first diaphragm 110 in such a way that the second diaphragm 120 rests on the second supporting elements 132 of the spacer elements 130. With the second diaphragm 120, which can in this case also be designed as a bending beam 124, and optional lateral edge elements 103, a micromechanical component 10 having a cavity 102 results in the region between the first and the second bending beams 124, i.e., again between the first diaphragm 110 and the second diaphragm 120. In addition, it is also possible that the first diaphragm 110 and the second diaphragm 120 are anchored at two ends and are respectively designed as a bending beam 124.

The first diaphragm 110 and the second diaphragm 120, and thus also the micromechanical diaphragm system 100, are divided into a free-end region 125 and an anchoring region 126. A plurality of spacer elements 130 is arranged both in the free-end region 125 and in the anchoring region 126. The anchoring region 126 is connected to the substrate 20; the free-end region 125 represents a free end of the bending beam 124. In the anchoring region 126, spacer elements 130 having spring elements 140 are arranged substantially in the second extension direction 109, which elements are designed as explained in connection with FIG. 3. Alternatively, these spacer elements may also correspond to one of the other exemplary embodiments having spring elements 140. In the free-end region 125, the spacer elements 130 are designed substantially in the first extension direction 108 as stiffening elements 138. A micromechanical diaphragm system 100 can thereby be provided, which has no or only a slight curvature in the free-end region 125 when the diaphragms 110, 120 and thus the micromechanical diaphragm system 100 are deflected in the vertical movement direction 101. Instead, the spacer elements 130 having spring elements 140 in the anchoring region 126 make a corresponding bending of the diaphragms 110, 120 and thus of the micromechanical diaphragm system 100 possible here.

In order to increase the clarity of FIG. 17, not all spacer elements 130 are shown. The stiffening elements 138 can consist of the same material and the same basic structure as the spacer elements 130 having spring elements 140. However, they differ in orientation and in the design of the spring elements 140.

FIG. 18 shows a flowchart 200 of a production method for a micromechanical diaphragm system 100. In a first method step 201, a first diaphragm layer is applied and is structured in a second method step 202. The first diaphragm 110 can thus be provided. A first sacrificial layer is subsequently applied to the first diaphragm layer in a third method step 203 and is structured in a fourth method step 204. A spring element layer is now applied on the first sacrificial layer in a fifth method step 205 and is structured in a sixth method step 206. The spacers 130 can thereby be provided. A second sacrificial layer is subsequently applied to the spring element layer in a seventh method step 207 and is structured in an eighth method step 208. A second diaphragm layer is subsequently applied to the second sacrificial layer in a ninth method step 209 and is structured in a tenth method step 210. The second diaphragm 120 can thereby be provided. The sacrificial layers are then removed in an eleventh method step 211.

If the micromechanical diaphragm system 100 is to contain the center electrode 106, the latter can be applied together with the spring elements 140 in the fifth method step 205 and can be structured in the sixth method step 206. Alternatively, however, additional method steps may also be provided for this purpose.

Although the present invention has been described in detail by means of the preferred exemplary embodiments, the present invention is not limited to the disclosed examples and other variations may be derived therefrom by a person skilled in the art without departing from the scope of protection of the present invention.

What is claimed is:

1. A micromechanical diaphragm system, comprising:
a first diaphragm;
a second diaphragm; and
spacer elements arranged between the first diaphragm and the second diaphragm, wherein at least one of the spacer elements has a first supporting element and a second supporting element, wherein the first supporting element faces the first diaphragm, wherein the second supporting element faces the second diaphragm, and wherein the first supporting element and the second supporting element are connected via a spring element.

2. The micromechanical diaphragm system according to claim 1, wherein the at least one of the spacer elements has a further first supporting element, wherein the further first supporting element and the second supporting element are connected via a further spring element.

3. The micromechanical diaphragm system according to claim 2, wherein the at least one of the spacer elements further includes a further second supporting element, wherein the first supporting element is connected via the spring element to a center element, wherein the further first supporting element is connected via the further spring element to the center element, wherein the center element is connected via the further spring element to the second supporting element, and wherein the center element is connected via the further spring element to the further second supporting element.

4. The micromechanical diaphragm system according to claim 2, wherein the spring element and/or the further spring element is a torsion spring.

5. The micromechanical diaphragm system according to claim 1, wherein the spring element is a folded spring element.

6. The micromechanical diaphragm system according to claim 1, wherein the first diaphragm and the second diaphragm are divided into an inner region and an outer region enclosing the inner region, wherein the spacer elements having the spring element are arranged in the outer region, wherein those of the spacer elements configured as stiffening elements are arranged in the inner region.

7. The micromechanical diaphragm system according to claim 1, wherein a closed cavity is arranged between the first and second diaphragms.

8. The micromechanical diaphragm system according to claim 7, wherein the cavity has a negative pressure, the negative pressure being a vacuum.

9. The micromechanical diaphragm system according to claim 1, wherein the micromechanical diaphragm system is a microelectromechanical diaphragm system, wherein the first diaphragm has a first diaphragm electrode, wherein the second diaphragm has a second diaphragm electrode, wherein a central support structure having at least one center electrode is arranged between the first diaphragm and the second diaphragm, wherein the center electrode has through-openings, and wherein the spacer elements are arranged in the through-openings).

10. The micromechanical diaphragm system according to claim 9, wherein the central support structure and the spacer elements are formed at least partially of the same material.

11. A micromechanical component for interacting with a pressure gradient of a fluid, comprising:
a substrate having a through-cavity; and
a micromechanical diaphragm system, the micromechanical diaphragm system at least partially spans the through-cavity, and the micromechanical diaphrragm system includes:
a first diaphragm,
a second diaphragm, and
spacer elements arranged between the first diaphragm and the second diaphragm, wherein at least one of the spacer elements has a first supporting element and a second supporting element, wherein the first supporting element faces the first diaphragm, wherein the second supporting element faces the second diaphragm, and wherein the first supporting element and the second supporting element are connected via a spring element.

12. A method for producing a micromechanical diaphragm system, comprising the following steps:
applying a first diaphragm layer;
structuring the first diaphragm layer;
applying a first sacrificial layer;
structuring the first sacrificial layer;
applying a spring element layer;
structuring the spring element layer;
applying a second sacrificial layer;
structuring the second sacrificial layer;
applying a second diaphragm layer;
structuring the second diaphragm layer;
removing the sacrificial layers.
